(19) United States
(12) Patent Application Publication
(10) Pub. No.: US 2026/0165099 A1
(43) Pub. Date: Jun. 11, 2026

(54) SHARED FIRST/SECOND PACKAGE DIE-TO-DIE INTERFACE DESIGN

(71) Applicant: Blue Cheetah Analog Design, Inc., Sunnyvale, CA (US)

(72) Inventor: Elad Alon, Lafayette, CA (US)

(73) Assignee: Blue Cheetah Analog Design, Inc., Sunnyvale, CA (US)

(21) Appl. No.: 18/976,928

(22) Filed: Dec. 11, 2024

(51) Int. Cl. H01L 21/768; H01L 23/00; H01L 23/528

(52) U.S. Cl. CPC H10W 20/031; H10W 20/435; H10W 72/01255; H10W 72/248

(57) ABSTRACT

Methods and apparatuses for semiconductor manufacture and packaging are described. In one example, a system for semiconductor manufacture includes a plurality of semiconductor processing masks configured to process a substrate during a plurality of semiconductor processing steps. The system includes a first mask option configured to process the substrate subsequent to the plurality of semiconductor processing steps to form first metal contacts suitable for use in a first semiconductor package type. A second mask option is configured to process the substrate subsequent to the plurality of semiconductor processing steps to form second metal contacts suitable for use in a second semiconductor package type.

### BACKGROUND OF THE INVENTION

Semiconductor packages can be divided into two general types, those referred to as “standard packages” and those referred to as “advanced packages.” A standard package refers to a packaging solutions that are widely available from a broad variety of suppliers, highly reliable, and cost effective. The connection densities of these packages are typically more limited than the “advanced package” solutions however. The primary differentiating feature of advanced packages are their much higher connection densities, but they are not as broadly available and typically substantially higher cost than the standard package alternatives.

Typically, silicon chiplet manufacturers must choose between a distinct standard package design or an advanced package design, which limits flexibility and necessitates trade-offs based on the specific application requirements.

### BRIEF DESCRIPTION OF THE DRAWINGS

The present invention will be readily understood by the following detailed description in conjunction with the accompanying drawings, wherein like reference numerals designate like structural elements.

FIG. 1 is a simplified partial cross-sectional side view illustration of a semiconductor structure processed using a mask set.

FIG. 2 illustrates a die-to-die (D2D) interface bump map of the semiconductor structure shown in FIG. 1 in one example.

FIG. 3 illustrates a mask for an advanced package configuration overlaid on the D2D bump map shown in FIG. 2.

FIG. 4 illustrates the semiconductor structure shown in FIG. 1 after further processing using the mask of FIG. 3, whereby solder bumps have been deposited.

FIG. 5 illustrates a mask for a standard package configuration overlaid on the D2D bump map depicted in FIG. 2.

FIG. 6 illustrates the semiconductor structure shown in FIG. 1 after further processing using the mask of FIG. 5, whereby solder bumps have been deposited.

FIG. 7 illustrates the D2D bump map overlaid with the mask in a standard packaging configuration with a visual representation of external metal interconnects.

FIG. 8 illustrates the D2D bump map overlaid with the mask in a standard packaging configuration, highlighting a specific metal layer including metal traces.

FIG. 9 illustrates a standard package configuration in which the depth of the mask overlay is increased to 770 μm, doubling the depth compared to the advanced package configuration.

FIGS. 10 and 11 illustrate a routing strategy within a standard package configuration, facilitated by increasing the depth of the mask overlay to 770 μm.

FIG. 12 illustrates the placement of bumps and their direct connections to the PHY bump map signal pads in a standard package configuration, in which the depth of the mask overlay is increased to 770 μm.

### DESCRIPTION OF SPECIFIC EMBODIMENTS

Methods and apparatuses for semiconductor manufacture and packaging are disclosed. In this description, specific configurations, dimensions, and processes are detailed to provide a comprehensive understanding of the embodiments. However, widely recognized semiconductor processes and manufacturing methods haven't been elaborated on to avoid obscuring the embodiments.

The following description is presented to enable any person skilled in the art to make and use the invention. Descriptions of specific embodiments and applications are provided only as examples and various modifications will be readily apparent to those skilled in the art. The general principles defined herein may be applied to other embodiments and applications without departing from the spirit and scope of the invention. Thus, the present invention is to be accorded the widest scope encompassing numerous alternatives, modifications and equivalents consistent with the principles and features disclosed herein.

In one example embodiment of the invention, both advanced and standard package versions of a semiconductor chip are built upon an identical silicon structure which is processed uniformly at the lower layers using a common (i.e., shared) mask set, regardless of the ultimate package type. The processes, ranging from the deposition of various silicon and metal layers to the etching and doping processes are identical at the lower levels. Differentiation occurs only at the uppermost metal layers where the physical layout and functionality of the bumps and their corresponding metal connections are defined.

The differences between the advanced and standard packages result from one or more mask changes between the package types to implement the uppermost layers, which may include changes associated with the geometries of the bumps, the metal layer coplanar with the lowest portion of the bump structures, and the vias that connect to this metal layer. For example, the advanced package version employs a mask with finely spaced apertures that dictate a densely populated array of bumps and metal connections. In contrast, the standard package version employs a mask with wider spaced apertures that dictate a sparser bump arrangement with metal traces specifically tailored to connect to the same underlying circuits. The interchange of one or more masks to implement the uppermost layers advantageously allows the same underlying semiconductor structure to be optimized for various packaging applications.

Having both advanced and standard packaging options for the same chip provides flexibility to target different market segments or applications. The advanced package may be used for more high-end products where performance is critical, while the standard package could target more cost-sensitive applications. Reuse of the underlying design reduces engineering efforts, simplifies manufacturing, and reduces cost compared to having completely separate chip designs for each package type.

In one example embodiment, a system for semiconductor manufacture includes a plurality of semiconductor processing masks configured to process a substrate during a plurality of semiconductor processing steps. Additionally, the system includes a first mask option configured to process the substrate subsequent to the plurality of semiconductor processing steps to form first metal contacts suitable for use in a first semiconductor package type. Furthermore, a second mask option is configured to process the substrate subsequent to the plurality of semiconductor processing steps to form second metal contacts suitable for use in a second semiconductor package type.

In one example embodiment, a method includes processing a substrate with a series of semiconductor processing masks across several semiconductor processing steps. The method includes selecting either a first mask option to form first metal contacts configured for a first semiconductor package type, or a second mask option to form second metal contacts configured for a second semiconductor package type.

In one example embodiment, a method includes processing a substrate using a plurality of semiconductor processing masks during a plurality of semiconductor processing steps. The method includes selecting either a first mask option or a second mask option, with the first mask option configured to process the substrate to form first metal contacts for a first semiconductor package type, and the second mask option configured to process the substrate to form second metal contacts for a second semiconductor package type. The method further includes processing the substrate utilizing the selected mask to create the designated metal contacts.

In one example embodiment, a semiconductor manufacturing system is configured to facilitate selectable semiconductor packaging processes. The system includes a substrate prepared through a series of lithographic semiconductor processing steps. The system includes a plurality of semiconductor processing masks, each associated with different layers of the substrate. The system further includes a first mask option and a second mask option designed for a top layer, where the first mask option is configured to form metal contacts and associated interconnects suitable for a first package type (e.g., an advanced semiconductor package type) with a defined first pitch, and the second mask option is configured to form metal contacts and associated interconnects suitable for a second package type (e.g., a standard semiconductor package type) with a defined second pitch. The second pitch is an integer multiple of the first pitch, facilitating the reconfiguration of packaging type with a mask change.

The first mask option or the second mask option is selected based on the desired semiconductor package type. The system utilizes lithographic techniques to apply the selected mask option to the substrate, thereby defining the physical and electrical characteristics of the top layer of the semiconductor device in accordance with the selected packaging type. The selection between the first mask option and the second mask option, and the consequent application thereof, enables a seamless transition between first and second packaging types, optimizing the use of underlying silicon geometries and internal metal layers without alteration, thereby enhancing manufacturing flexibility and efficiency.

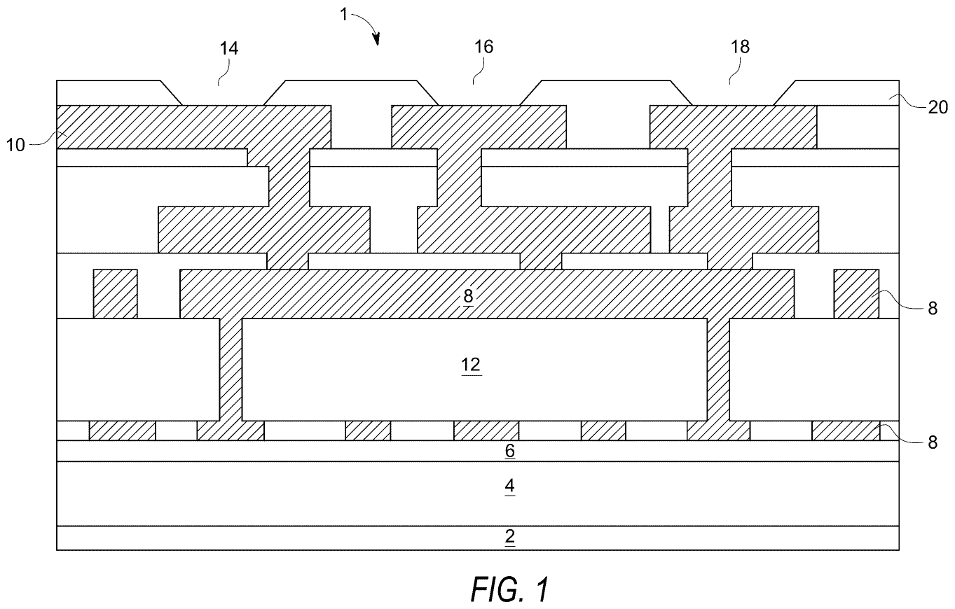

Referring now to FIG. 1, a simplified partial cross-sectional side view illustration is provided of a semiconductor structure 1 fabricated using a common mask set for packaging in an advanced package or a standard package. A semiconductor material, exemplified as a silicon wafer 2, serves as the base for constructing the semiconductor structure 1. A substrate layer 4 is deposited or grown on the silicon wafer 2. For example, substrate layer 4 may be formed using epitaxial growth among other processes to prepare a suitable surface for the fabrication of both active and passive devices. Positioned above the substrate layer 4 is a device layer 6, where semiconductor devices such as transistors, capacitors, or resistors are patterned and created. This layer's formation involves several stages, including doping, isolation, and gate formation, each necessitating a unique photolithography mask in the common mask set for the precise deposition and etching of materials.

Above the device layer 6, multiple layers of metal interconnects, identified as metal interconnects 8, are established, interspersed with dielectric layers 12. Metal interconnects 8 forge the pathways that electrically connect the devices within the chip, thus enabling the integrated circuit to perform its intended functions. The patterning of these metal and dielectric layers is executed through photolithography, employing distinct masks in the common mask set for each layer to ensure accurate alignment and connectivity.

An interconnect top layer 10 is added as the final metal layer. Interconnect top layer 10 includes terminal metal pads intended for external connections to the chip. Positioned above the interconnect top layer 10 is a passivation layer 20, having openings (e.g., opening 14, opening 16, and opening 18) that expose the interconnect top layer 10 for the deposition of solder bumps. These solder bumps forge electrical connections with external circuitry or with the substrates used in packaging, ensuring electrical pathways for signal transmission and power distribution between the semiconductor device and other components within an electronic system. Deposition of the solder bumps is discussed in further detail below.

The passivation layer 20, typically formed from a dielectric compound such as Silicon Nitride (Si3N4) or Silicon Dioxide (SiO2), serves to protect the underlying semiconductor structure and metal layers from environmental harm, such as contamination and moisture, as well as from mechanical damage. Moreover, the passivation layer 20 electrically isolates the top interconnect top layer 10 from unintended contacts, except at the specified openings 14, 16, and 18 where solder bumps are intended to be established.

The photolithography process using the common mask set defines each layer's structure and connectivity within the semiconductor structure 1. This process involves the application of a photoresist and its exposure through a mask tailored to each layer's pattern. The exposed or developed areas of the photoresist allow for the etching process to remove unwanted materials, creating precise structures and patterns on the substrate. Similarly, material deposition techniques are employed to add new materials to defined areas, building up the semiconductor layers. These processes of etching away undesired material and depositing required layers transform the patterned photoresist into the actual physical structures of the device.

While FIG. 1 provides a simplified partial cross-sectional view of the semiconductor structure 1, the actual construction may incorporate additional components and layers not illustrated. These elements include but are not limited to well regions, gate dielectrics, and various isolation and interconnection strategies. Beneath the device layer 6, n-well or p-well regions may be formed within the substrate layer 4 to provide isolated environments for complementary transistors. Atop the device region 6, a gate dielectric layer is typically grown, followed by the deposition of a conductive gate material, establishing the gate structure of MOS transistors. This gate dielectric may comprise silicon dioxide or high-k materials, whereas the gate itself is often formed from polysilicon or metal, depending on the device architecture.

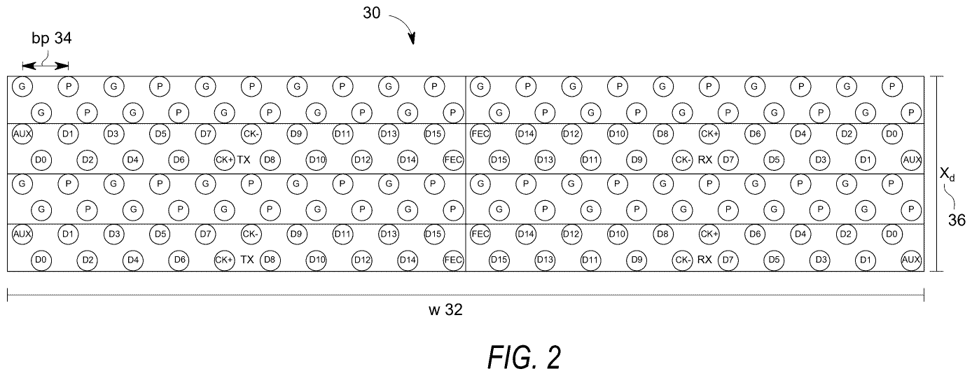

FIG. 2 illustrates a D2D bump map 30 of the semiconductor structure 1 shown in FIG. 1 in one example. D2D bump map 30 indicates a width w 32, bump pitch (bp) 34, and depth x_{d} 36. In one embodiment, width w 32 is approximately 1.1 mm. Bump pitch 34 is the distance between adjacent solder bumps, and can be measured center-to-center or edge-to-edge. For example, PHY bump map 30 is for a two stack, two transmitter (Tx), two receiver (Rx), 60 um signal pad device.

The D2D bump map 30 provides a visual guide for the placement of solder bumps in the semiconductor packaging process, ensuring each physical connection is accurately implemented in accordance with the design requirements of the device. In the provided D2D bump map 30, an array of labeled pads is arranged in a grid-like configuration, indicative of the connections required for the physical layer interfaces of a semiconductor device. The labeled pads include:
G: Ground connections, which serve as the common reference point for the circuit.
P: Power connections that supply necessary operating voltages for the semiconductor device's functionality.
AUX: Auxiliary connections that facilitate additional functionalities such as control signals or configuration settings.
D0, D1, D2, . . . , D15: Data connections for transmitting or receiving information within the device's communication interface.
CK: The clock signal that synchronizes the timing of data transmissions across the device.
FEC: Forward Error Correction, which refers to a system of error control for data transmission that allows the receiver to detect and correct errors autonomously.

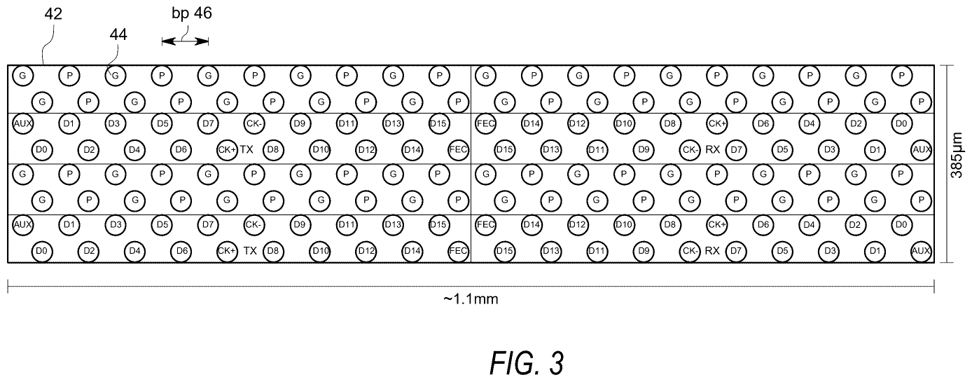

FIG. 3 illustrates an overlay of a mask 42 on the D2D bump map 30 shown in FIG. 2. Mask 42 is configured for use following the common mask set to process the semiconductor structure 1 for packaging in an advanced semiconductor package type. In one example, mask 42 is a lithographic mask designed for the very top metal layer related to the bumps and interconnects (i.e., metal traces) for the advanced package type. Mask 42 is a plate made of a transparent substrate, typically quartz or fused silica, which is coated with a thin layer of metal, usually chromium.

In the photolithography process, mask 42 is precisely aligned over the semiconductor wafer, which has previously been coated with a photoresist layer. Once alignment is confirmed, the assembly is exposed to ultraviolet (UV) light. The design of the mask features opaque areas which block the UV light, and clear areas that permit UV light to pass through. This selective exposure allows the UV light to modify the photoresist beneath the clear sections of the mask.

Following exposure, the wafer undergoes development where the photoresist that was exposed to the UV light is washed away, depending on whether a positive or negative photoresist is used. This leaves behind a pattern on the wafer that directly corresponds to the design of the mask. The subsequent step involves etching, where the areas of the wafer now exposed by the removed photoresist are etched away or alternatively, new materials may be deposited. This final etching or deposition step effectively transfers the mask 42 pattern, which may include the designs for both the bumps (e.g., apertures 44) and the connecting metal traces, onto the wafer itself, shaping the topography of the semiconductor's surface for advanced package functionality.

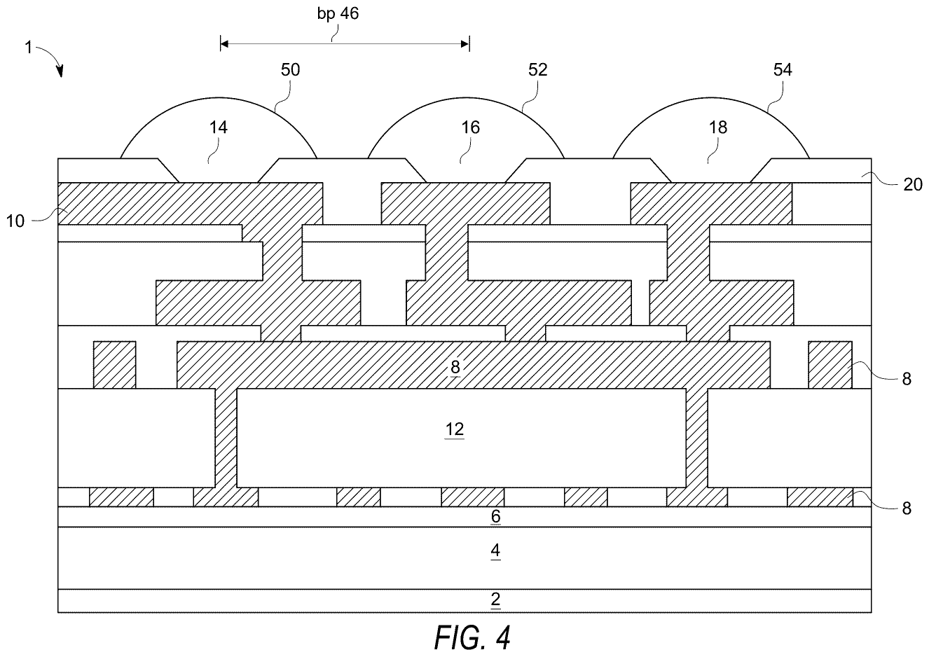

For example, mask 42 is used to create the solder bump pattern as outlined in the PHY bump map 30 shown in FIG. 2. In the fabrication process, apertures 44 are arranged to align directly with every labeled physical interface connection detailed on the PHY bump map 30. As such, bump pitch 46 shown in FIG. 3 is equal to bump pitch 34 shown in FIG. 2. In this non-limiting example, apertures 44 are spaced at intervals of 60 μm. In further examples, this bump pitch 46 may be varied, such as intervals of 65 μm. In one example, mask 42 has a depth x_{d}=385 μm for the advanced package. Shoreline bandwidth density is one factor in assessing the impact of interconnect density on semiconductor package performance. The shoreline bandwidth density for mask 42 is 2*256 GB/s//0.6 mm=853.33 Gb/s/mm. FIG. 4 illustrates the semiconductor structure shown in FIG. 1 after further processing using the mask 42 for packaging in an advanced semiconductor package type, whereby solder bump 50, solder bump 52, and solder bump 54 have been deposited over openings 14, 16, and 18 with a bump pitch 46.

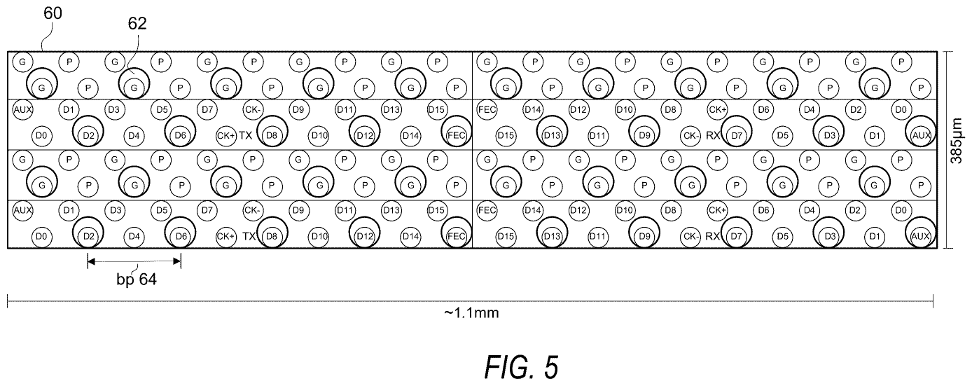

Referring now to FIG. 5, a mask 60 is overlaid on the D2D bump map 30 depicted in FIG. 2. Mask 60 is configured for use following the common mask set to process the semiconductor structure 1 for packaging in a standard semiconductor package type. Advantageously, the use of mask 60 allows semiconductor structure 1 to be packaged in a standard semiconductor package by utilizing only selected components of the underlying chip. Processing of semiconductor structure 1 is identical up until the selection of either mask 42 or mask 60.

The overlay of mask 60 on D2D bump map 30 shows apertures 62 that align with the pads designated for use in the standard packaging version in one example. Mask 60 has a bump pitch 64. The pattern of mask 60 and its alignment with specific pads on D2D bump map 30 determines which connections are prioritized for the standard package, and this alignment reveals intentional gaps or shifts where apertures 62 do not match up with every labeled pad, reflecting a configuration that accommodates a less dense interconnect scheme. Unlike an advanced package where an aperture corresponds to every pad on the D2D bump map 30, mask 60 for the standard package aligns apertures 62 with alternate pads or a less dense configuration. Certain pads, such as some data lines (D0-D15) and some auxiliary, power, and ground connections, have corresponding apertures 62, while others do not.

In one example, mask 60 has a depth x_{d}=385 μm for the standard package, the same depth as for the advanced package. In this example configuration, the shoreline bandwidth density for the standard package drops by a factor of 4 relative to the advanced package: 128 Gb/s/0.6 mm=213.33 Gb/s/mm. This density indicates a moderated data transfer capability suited for applications not requiring extreme performance speeds. As described previously, the advanced package supports a bandwidth density of 853.33 Gb/s/mm.

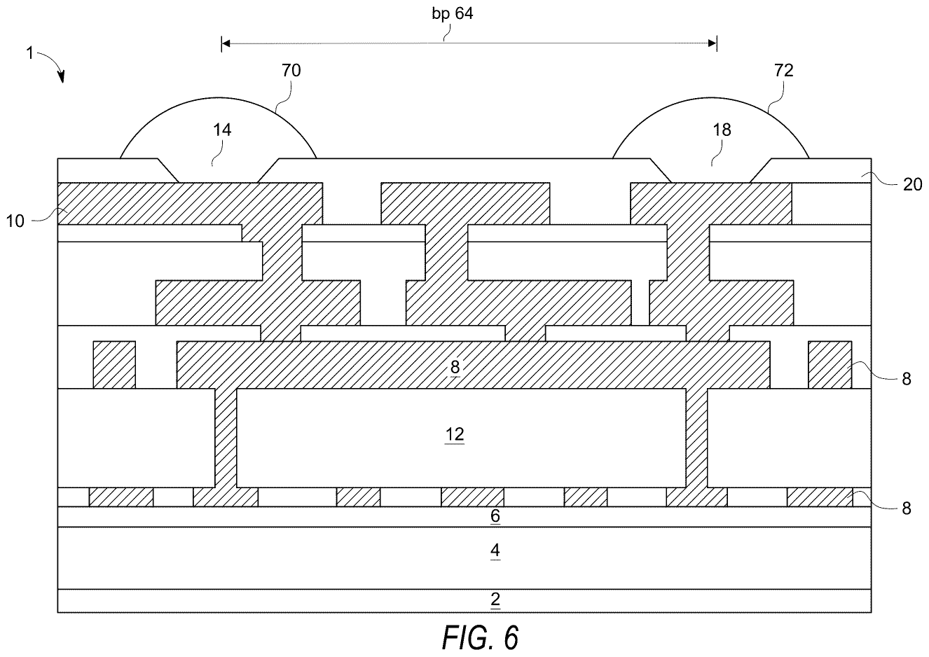

Mask 60 is designed for standard packaging, where the need for a lower connection density and a focus on cost efficiency and simplicity are predominant. By reducing the number of interconnections, this design simplifies the overall packaging process. FIG. 6 illustrates the semiconductor structure shown in FIG. 1 after further processing using the mask 60 for packaging in a standard semiconductor package type, whereby solder bump 70 has been deposited over opening 14 and solder bump 72 has been deposited over opening 18 with a bump pitch 64.

The inventor has recognized that in one particularly advantageous embodiment, the bump pitch differential between advanced and standard package types is set at an integer multiple, i.e., standard package bump pitch 64 is an integer multiple of advanced package bump pitch 46, such as a multiple of 2. For example, where apertures 44 are spaced at intervals of 60 μm, apertures 62 are spaced at 120 μm. Similarly, where apertures 44 are spaced at intervals of 65 μm, apertures 62 are spaced at 130 μm.

The inventor has identified several key advantages of locking the pitch between the advanced and standard packages to an integer multiple, such as a factor of two. It enables always using the exact same I/O circuit layout style for signals, data, and clocks in both package types. This provides consistency. The lengths of routes between where the I/O cells would be physically placed in the advanced package versus the standard package is kept fairly short. This optimizes routing efficiency. The routing is also kept reasonably well balanced between the two package versions since the pitch relationship is a simple factor of two ratio. This simplifies routing design. By enforcing this pitch constraint, all the rewiring needed between the advanced and standard package bump configurations becomes a regular and repeated pattern. This makes the routing design as well as the design of the chiplets more straightforward.

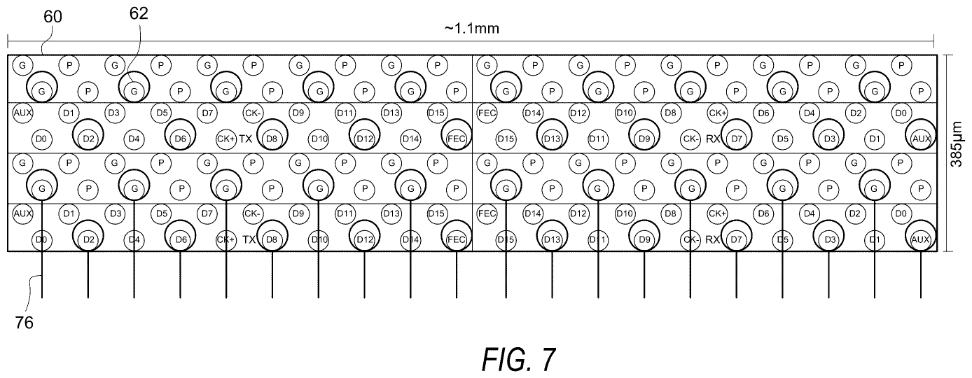

FIG. 7 illustrates the D2D bump map 30 overlaid with mask 60 with a visual representation of external metal interconnects 76 as part of a standard packaging configuration. For example, metal interconnects are formed from copper or aluminum. External metal interconnects 76, formed on the package itself, are designed to route signals from the solder bumps on the chip to other parts of the package, facilitating connections with another chip or component, typically situated on the opposite side of the package.

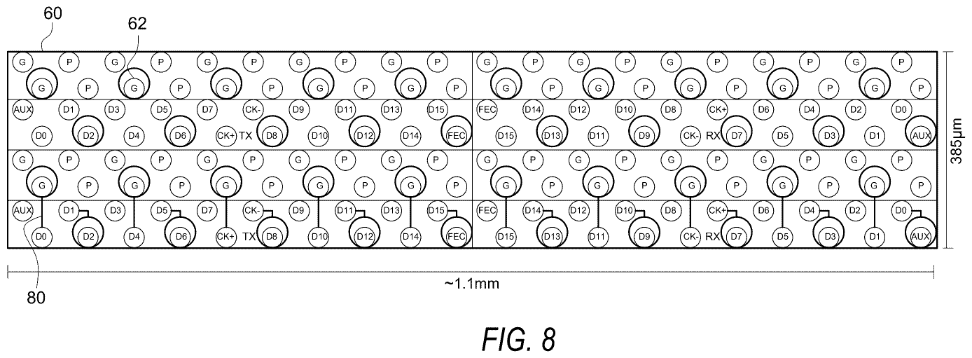

FIG. 8 illustrates a detailed view of the D2D bump map 30 with an overlay of mask 60, highlighting a specific metal layer including metal traces 80 in a standard packaging configuration. Metal traces 80 extend from selected bump locations, illustrating the pathway for electrical connectivity directly on the chip itself. Metal traces 80 are designed to connect the solder bumps to the corresponding circuit elements within the chip in a standard package.

As shown in FIG. 8, while the circuitry for advanced packaging configurations remains intact, not all circuits are utilized in the standard package. The bumps depicted are strategically placed to emulate the physical positions they would occupy in an advanced packaging configuration, and imply additional connections necessary to align them physically with the bump locations as configured for advanced packaging. This illustrates the selective use and non-use of available circuits within this example standard packaging layout.

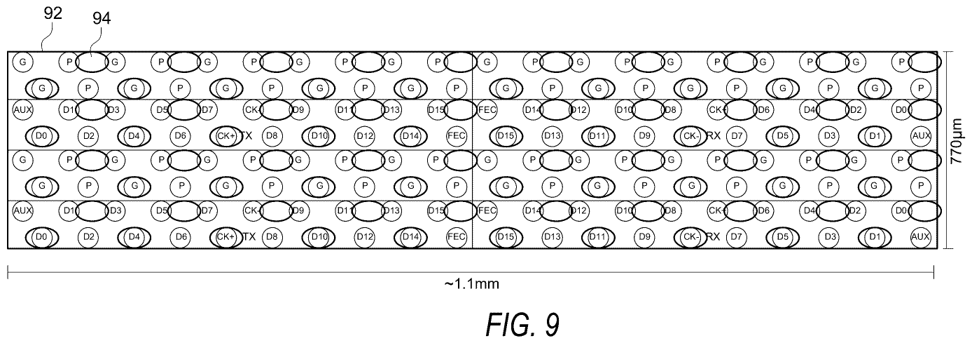

FIGS. 9-12 illustrate an example in which the depth x_{d} of the mask for the standard package has been doubled to 770 μm. This modification allows fitting the same number of bumps within the standard package footprint despite the larger spacing between bumps. The inventor has recognized several advantages in doubling the depth x_{d}. It simplifies routing due to reduced spatial changes and increases utilization of the underlying hardware. For example, this depth alteration allows for simplified connections, where bumps can be strategically placed directly above or staggered relative to those in advanced packages. Whereas previously only approximately a quarter of the circuitry was usable in the standard package, doubling the depth increases this to approximately half of the total circuity. This enables signals to be routed to one set of bumps, and power to another set of bumps within the same unit element, in a similar manner to the advanced package version. The increased routing complexity and irregularity associated with only being able to use a quarter of the circuitry is avoided by doubling the depth to recover half of the circuitry instead.

Referring now to FIG. 9, a mask 92 having apertures 94 is overlaid on the PHY bump map 30 depicted in FIG. 2. In this example, the depth x_{d} has been increased by a factor of two, such that x_{d}=770 μm. As a result, this standard package configuration features a shoreline bandwidth density of 426.67 Gb/s/mm, calculated from a shoreline bandwidth of 2*128 GB/s over a 0.6 mm interface width. Advantageously, with the increased depth, the bandwidth density has doubled from the example when x_{d}=385 μm shown in FIGS. 5-8. In this example configuration, the improved shoreline bandwidth density for the standard package drops by a factor of only two relative to the advanced package value of 853.33 Gb/s/mm.

In one embodiment, when the bump depth is doubled in the standard package configuration, the existing redundancy features (e.g., AUX and FEC lines) utilized in the advanced package configuration are leveraged to improve the routing efficiency. These redundancy lines enable workarounds for potential manufacturing defects that may arise during the assembly and packaging process. Advantageously, the existing redundancy features allow recovering more of the circuitry connectivity in the standard package version compared to if those redundancy features were not present and utilized from the advanced package design. Routing is improved by avoiding having to make do with significantly fewer interconnects.

When transitioning to a standard package configuration, the design reduces the number of connections by half while selectively eliminating certain redundancy paths, which simplifies the overall bump configuration. The unit cell width in the standard package configuration is half that of the advanced package configuration, reflecting the removal of some redundancy paths.

For example, in an advanced package configuration, ten columns of bumps are required. This total is based on the need for sixteen data lines, two redundancy lines, and two clocks resulting in twenty bumps in total arranged in two rows. In the standard package configuration, where only eight data lines are required, a total of ten bumps are used. This arrangement advantageously fits into exactly half as many columns (i.e., five) as the advanced package configuration.

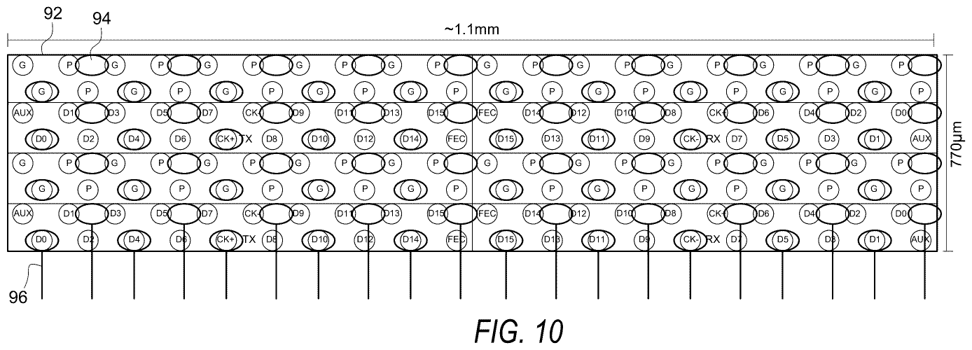

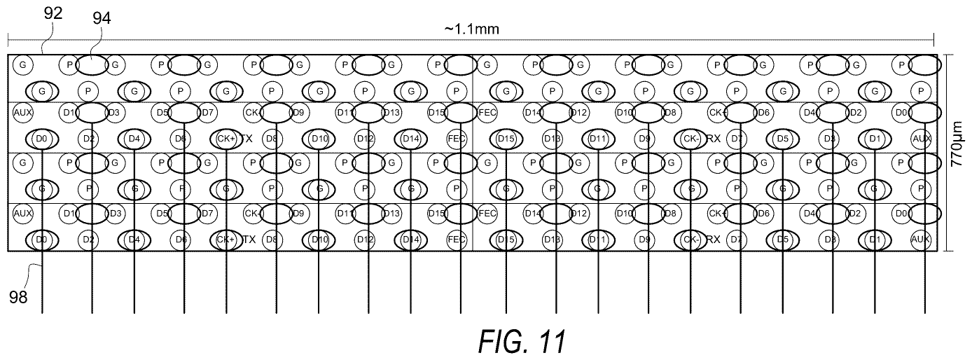

FIGS. 10 and 11 illustrate a routing strategy within a standard package configuration, facilitated by doubling the depth, x_{d}, to 770 micrometers. Multiple layers in the package are utilized to route the signals efficiently from the die to the package pins or other connecting structures. FIG. 10 illustrates how one metal layer manages the signal routes 96 closer to the die edge, effectively utilizing the space near the periphery of the die. FIG. 11 illustrates a second metal layer which handles the signal routes 98 originating deeper within the die.

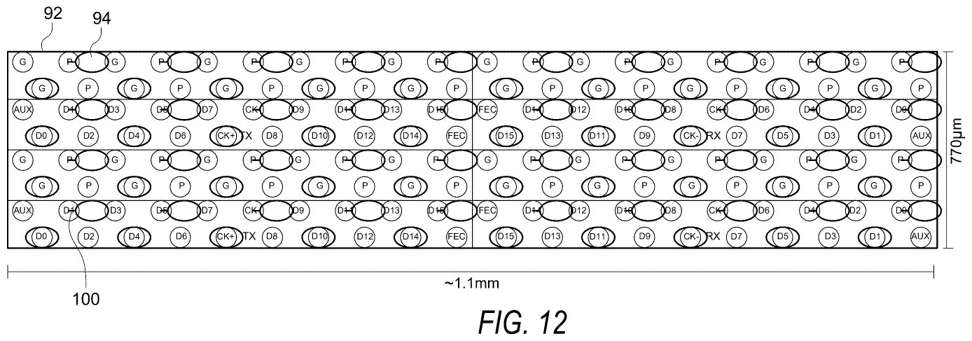

FIG. 12 illustrates the placement of bumps (shown as ovals) and their direct connections to the D2D bump map signal pads. Metal traces 100 extend from each bump to connect to the corresponding signal pads. At points along the die edge, where bumps are positioned directly over the D2D signal pads, additional routing is not required, simplifying the design at these junctions. FIG. 12 illustrates the rerouting necessary to replicate the advanced package's interconnect layout within the standard package's constraints, imposed by the expanded depth. Each bump is connected back to what would have been their positions in the advanced package, thus maintaining functional integrity despite the standard package's broader pitch settings. The redistribution layer (RDL) on the standard package adapts to ensure that the bumps align effectively with their intended signal pads as per the more densely configured advanced packaging. Although the bumps' physical locations change, the underlying circuitry can remain the same.

In utilizing the various aspects of the embodiments, it would become apparent to one skilled in the art that combinations or variations of the above embodiments are possible. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

The functionality that is described as being performed by a single system component may be performed by multiple components. Similarly, a single component may be configured to perform functionality that is described as being performed by multiple components. For purpose of clarity, details relating to technical material that is known in the technical fields related to the invention have not been described in detail so as not to unnecessarily obscure the present invention. It is to be understood that various example of the invention, although different, are not necessarily mutually exclusive. Thus, a particular feature, characteristic, or structure described in one example embodiment may be included within other embodiments unless otherwise noted.

While the exemplary embodiments of the present invention are described and illustrated herein, it will be appreciated that they are merely illustrative and that modifications can be made to these embodiments without departing from the spirit and scope of the invention. Acts described herein may be implemented as a hardware design. Acts described herein may be computer readable and executable instructions that can be implemented by one or more processors and stored on a computer readable memory or articles. The computer readable and executable instructions may include, for example, application programs, program modules, routines and subroutines, a thread of execution, and the like. In some instances, not all acts may be required to be implemented in a methodology described herein.

The described subject matter may be implemented as an apparatus, a method, or article of manufacture using standard programming or engineering techniques to produce software, firmware, hardware, or any combination thereof to control one or more computing devices. Thus, the scope of the invention is intended to be defined only in terms of the following claims as may be amended, with each claim being expressly incorporated into this Description of Specific Embodiments as an embodiment of the invention.

What is claimed is:

1. A method for a semiconductor manufacture comprising:
processing a substrate using a plurality of semiconductor processing masks during a plurality of semiconductor processing steps;
selecting one from a first mask option and a second mask option subsequent to the plurality of semiconductor processing steps, wherein the first mask option is configured to process the substrate subsequent to the plurality of semiconductor processing steps to form first metal contacts suitable for use in a first semiconductor package type, and the second mask option is configured to process the substrate subsequent to the plurality of semiconductor processing steps to form second metal contacts suitable for use in a second semiconductor package type;
processing the substrate utilizing the selected first mask option to form the first metal contacts or the selected second mask option to form the second metal contacts.

2. The method of claim 1, wherein the first semiconductor package type comprises an advanced package type and the second semiconductor package type comprises a standard package type.

3. The method of claim 1, wherein the first mask option is patterned for a first bump pitch, and the second mask option is patterned for a second bump pitch, wherein the second bump pitch is an integer multiple of the first bump pitch.

4. The method of claim 3, wherein the second bump pitch is twice the first bump pitch.

5. The method of claim 1, wherein the plurality of semiconductor processing steps fabricates a plurality of electronic devices and interconnect structures.

6. The method of claim 1, wherein the first metal contacts comprise first bump formations and the second metal contacts comprise second bump formations.

7. The method of claim 1, wherein the first mask option comprises a first depth and the second mask option comprises a second depth, wherein the first depth is equal to the second depth.

8. The method of claim 1, wherein the first mask option comprises a first depth and the second mask option comprises a second depth, wherein the second depth is an integer multiple of the first depth.

9. The method of claim 8, wherein the second depth is twice the first depth.

10. A system for a semiconductor manufacture comprising:
a plurality of semiconductor processing masks configured to process a substrate during a plurality of semiconductor processing steps;
a first mask option configured to process the substrate subsequent to the plurality of semiconductor processing steps to form first metal contacts suitable for use in a first semiconductor package type; and
a second mask option configured to process the substrate subsequent to the plurality of semiconductor processing steps to form second metal contacts suitable for use in a second semiconductor package type.

11. The system of claim 10, wherein the first semiconductor package type comprises an advanced package type and the second semiconductor package type comprises a standard package type.

12. The system of claim 10, wherein the first mask option is patterned for a first bump pitch, and the second mask option is patterned for a second bump pitch, wherein the second bump pitch is an integer multiple of the first bump pitch.

13. The system of claim 12, wherein the second bump pitch is twice the first bump pitch.

14. The system of claim 10, wherein the plurality of semiconductor processing steps fabricates a plurality of electronic devices and interconnect structures.

15. The system of claim 10, wherein the first metal contacts comprise first bump formations and the second metal contacts comprise second bump formations.

16. The system of claim 10, wherein the first mask option comprises a first depth and the second mask option comprises a second depth, wherein the first depth is equal to the second depth.

17. The system of claim 10, wherein the first mask option comprises a first depth and the second mask option comprises a second depth, wherein the second depth is an integer multiple of the first depth.

18. The system of claim 17, wherein the second depth is twice the first depth.
